(19) United States
(12) Patent Application Publication
(10) Pub. No.: US 2026/0118769 A1
(43) Pub. Date: Apr. 30, 2026

(54) POLYMER MATERIAL-BASED METHOD FOR REMOVING METAL FILM LAYER FROM SURFACE OF SUBSTRATE AND PHOTOLITHOGRAPHY METHOD

(71) Applicant: THE INSTITUTE OF OPTICS AND ELECTRONICS, THE CHINESE ACADEMY OF SCIENCES, Chengdu, Sichuan (CN)

(72) Inventors: Xiangang Luo, Chengdu, Sichuan (CN); Tao Shen, Chengdu, Sichuan (CN); Ling Liu, Chengdu, Sichuan (CN); Zeyu Zhao, Chengdu, Sichuan (CN); Danglong Zhang, Chengdu, Sichuan (CN)

(21) Appl. No.: 19/136,305

(22) PCT Filed: Aug. 23, 2023
(86) PCT No.: PCT/CN2023/114428

§ 371 Date: Jun. 6, 2025

(30) Foreign Application Priority Data
Dec. 6, 2022 (CN) 202211555383.X

(51) Int. Cl. G03F 7/32; C09D 5/20; C09D 7/63; C09D 129/04; C09D 183/04; G03F 7/20

(52) U.S. Cl. CPC G03F 7/32; C09D 5/20; C09D 7/63; C09D 129/04; C09D 183/04; G03F 7/2026

(57) ABSTRACT

A method for removing a metal film layer from a surface of a substrate based on polymer material, comprising: S1, preparing a super-resolution photolithographic structure, wherein the super-resolution photolithographic structure sequentially comprises a substrate, a reflective metal film layer, a photosensitive film layer and a transmissive metal film layer from bottom to top to form a metal-dielectric-metal plasma cavity imaging structure; S2, exposing the photosensitive film layer in the plasma cavity imaging structure by utilizing a super-resolution photolithography; S3, coating a high-molecular polymer solution onto the transmissive metal film layer, and heating to cure the high-molecular polymer solution to form a polymer film; and S4, stripping the polymer film, while simultaneously the transmissive metal film layer which is adhered to the polymer film is completely stripped without damaging the photosensitive film layer and the reflective metal film layer.

The present disclosure claims the priority to the Chinese patent application with the filing No. 202211555383.X filed on Dec. 6, 2022, the contents of which are incorporated herein by reference in entirety.

### TECHNICAL FIELD

The present disclosure relates to the technical field of super-resolution imaging, in particular to a method for removing a metal film layer from the surface of a substrate based on polymer material and a photolithography method.

### BACKGROUND ART

With the continuous improvement of device integration and the ongoing scaling down of semiconductor process nodes, new challenges have been proposed for optical imaging lithography systems and lithographic development processes. Compared with the traditional projection imaging optical photolithography system, surface plasmons (SP) super-resolution imaging photolithography can use nano-metal imaging film structure such as superlens to excite SP mode in spatial frequency spectrum range and enhance the intensity of evanescent wave carrying high-frequency spatial information, thus breaking through the resolution limits of traditional projection imaging optical photolithography and realizing the high-fidelity transfer of mask patterns to photoresist space for super-resolution imaging photolithography.

On the one hand, in order to further improve the SP excitation efficiency and compress the SP wavelength, the traditional SP superlens structure is combined with an SP reflective imaging structure, and their advantages are integrated to form an SP resonant cavity imaging structure composed of metal-dielectric (photoresist)-metal. Theoretically, the SP resonant cavity imaging structure exhibits higher imaging resolution and pattern depth.

On the other hand, in the micro-nano process system matched with SP super-resolution imaging photolithography technology, in order to achieve the development and patterning of photoresist layer after photosensitization within the SP resonant cavity imaging structure, it is necessary to strip the upper metal layer in the resonant imaging structure. Currently, the removal of the upper metal layer typically relies on chemical reactions using acids that react with metals. For example, for metallic silver, nitric acid is usually used. However, such strong oxidizing acids are incompatible with the photoresist used to achieve super resolution. At the same time, wet removal techniques suffer from poor controllability, and the stability of the process is limited by the influence of environmental temperature and liquid concentration gradient. For example, the negative development process was developed to improve the resolution of via and trench structures. The process adopts positive photoresist exposure and negative developer to achieve the same effect as negative photoresist development. The bright-field mask adopted in this process has higher pattern contrast and larger process window for smaller-sized lines and holes, providing greater advantages in high-resolution applications.

Therefore, if SP resonant cavity imaging technology is combined with negative development process, it is likely to break through the existing technical nodes. However, in the actual process experiment, since the photoresist in the SP resonant cavity is sandwiched between two layers of metal, the exposed pattern cannot be developed until the surface metal is removed. Conventional metal removal methods cause certain damage and destruction to both the photoresist layer and the underlying metal layer, making it impossible to obtain the pattern structure. At the same time, in the negative development process, the exposed area of photoresist becomes a hydrophilic polymer, the water and common alkaline solutions (developer) cannot be used. Conventional wet etching solution of metals inevitably contains water, and post-removal rinsing after metal removal with water is necessary to avoid damaging the photoresist and underlying metal, making it incompatible with the negative development process.

Therefore, developing a simple, effective and non-destructive technique for stripping the surface metal layer will be the key technology of photolithography process to realize the combination of SP resonant cavity imaging technology and negative development process.

### SUMMARY

### I. The Technical Problems to be Solved

In view of the above problems, a method for removing a metal film layer from the surface of a substrate based on polymer material and a photolithography method are provided in the present disclosure, which are used to solve the technical problems that the conventional method causes certain damage and destruction to both the photoresist layer and the underlying metal layer, and is incompatible with the negative development process.

### II. Technical Solutions

On the one hand, a method for removing a metal film layer from the surface of a substrate based on polymer material is provided in the present disclosure, including: S1, preparing a super-resolution photolithographic structure, wherein the super-resolution photolithographic structure sequentially includes a substrate, a reflective metal film layer, a photosensitive film layer and a transmissive metal film layer from bottom to top to form a metal-dielectric-metal plasma cavity imaging structure; S2, exposing the photosensitive film layer in the plasma cavity imaging structure by utilizing super-resolution photolithography; S3, coating a high-molecular polymer solution onto the transmissive metal film layer, and heating to cure the high-molecular polymer solution to form a polymer film; and S4, stripping the polymer film, while simultaneously the transmissive metal film layer which is adhered to the polymer film is completely stripped without damaging the photosensitive film layer and the reflective metal film layer.

Further, S1 includes: preparing a reflective metal film layer on a substrate by magnetron sputtering deposition, thermal evaporation deposition or chemical vapor deposition, wherein the substrate includes one of a silicon substrate, a quartz substrate, a sapphire substrate, a magnesium fluoride substrate, and a flexible substrate. The substrate includes a planar substrate or a curved substrate. The material of the reflective metal film layer includes one of Ag, Al and Au, with a thickness of 10-200 nm.

Further, S1 includes: preparing a transmissive metal film layer on the photosensitive film layer by a magnetron sputtering deposition, an atomic layer deposition, a chemical vapor deposition or a vacuum evaporation deposition, wherein the photosensitive film layer includes one of the AR series photoresist and AZ series photoresist, with a thickness of 10-200 nm. The material of the transmissive metal film layer includes one of Ag, Al and Au, with a thickness of 10-30 nm.

Further, S2 includes: exposing the photosensitive film layer in the plasma cavity imaging structure through a mask by using an ultraviolet illumination light source, wherein the mask pattern structure in the mask includes one of a one-dimensional pattern structure and a two-dimensional pattern structure.

Further, the high-molecular polymer solution includes: silicone rubber solution, or a combination solution of polyvinyl alcohol and polyvinylpyrrolidone, or a combination solution of polyvinyl alcohol and melamine. The polyvinyl alcohol has a polymerization degree of 500-2000 and an alcoholysis degree of 87%-89%. The high-molecular polymer solution is determined according to the bonding force between the photosensitive film layer and the transmissive metal film layer.

Further, the silicone rubber solution includes polydimethylsiloxane. S3 includes: S311, mixing polydimethylsiloxane and a curing agent uniformly for crosslinking to obtain a crosslinked mixed solution; S312, vacuumizing to remove bubbles in the mixed solution; S313, pouring the mixed solution obtained in S312 onto the transmissive metal film layer, and spin-coating at the rotating speed of 300-500 rpm for 30-60 seconds; and S314, heating at 75-85° C. for 15-25 minutes to cure the mixed solution, so as to form a polymer film.

Further, the high-molecular polymer solution is a combination solution of polyvinyl alcohol and melamine or a combination solution of polyvinyl alcohol and polyvinylpyrrolidone. S3 includes: S321, mixing polyvinyl alcohol, polyvinylpyrrolidone or melamine, and deionized water uniformly to obtain a mixed solution; S322, stirring the mixed solution fully in a water bath or an oil bath at 70-80° C. for 3-5 h, and standing; S323, pouring the mixed solution obtained in S322 onto the transmissive metal film layer, and spin-coating at the rotating speed of 300-500 rpm for 30-60 seconds; and S324, heating at 60-80° C. for 2-10 minutes to cure the mixed solution, so as to form a polymer film.

Further, S4 includes: adjusting the adhesion between the polymer film and the transmissive metal film layer by changing the viscosity and the degree of curing of the high-molecular polymer in the high-molecular polymer solution, so that the transmissive metal film layer adheres to the polymer film and is completely stripped without damaging the photosensitive film layer and the reflective metal film layer.

On the other hand, a photolithography method with removing a metal film layer from the surface of a substrate based on polymer material is provided in the present disclosure, including: S1, preparing a super-resolution photolithographic structure, wherein the super-resolution photolithographic structure sequentially includes a substrate, a reflective metal film layer, a photosensitive film layer and a transmissive metal film layer from bottom to top to form a metal-dielectric-metal plasma cavity imaging structure; S2, exposing the photosensitive film layer in the plasma cavity imaging structure by utilizing super-resolution photolithography; S3, coating a high-molecular polymer solution onto the transmissive metal film layer, and heating to cure the high-molecular polymer solution to form a polymer film; S4, stripping the polymer film, while simultaneously the transmissive metal film layer which is adhered to the polymer film is completely stripped without damaging the photosensitive film layer and the reflective metal film layer; and S5, performing negative development on the photosensitive film layer by using an organic solvent, so as to obtain a super-resolution photolithographic pattern structure.

Further, the organic solvent in S5 includes one or more of ketones, ethers and esters.

### III. The Beneficial Effects

According to the method for removing a metal film layer from the surface of a substrate based on polymer material and the photolithography method provided in the present disclosure, a high-molecular polymer is adopted as an adhesion layer, so as to simply and efficiently remove the transmissive metal film layer from the surface of the substrate without damaging or destroying the lower photosensitive film layer and the reflective metal film layer, which is advantageous for obtaining a high-quality super-resolution photolithographic pattern. Specifically, by changing the viscosity and the degree of curing of the high-molecular polymer in the high-molecular polymer solution, the adhesion between the polymer film and the transmissive metal film layer can be accurately regulated, and the transmissive metal film layer can be completely stripped. The method is applicable to the interface between the photosensitive film layer and the transmissive metal film layer with different adhesion strengths, and the method is also very compatible with the negative development process, so that the photolithography quality of high-resolution patterns is improved, thus providing an important foundation for subsequent pattern transmission.

### BRIEF DESCRIPTION OF THE DRAWINGS

FIG. 1 schematically illustrates a flow chart of a method for removing a metal film layer from the surface of the substrate based on polymer material according to an example of the present disclosure.

FIG. 2 schematically illustrates a structural schematic diagram of super-resolution photolithography according to an example of the present disclosure.

FIG. 3 schematically illustrates the structural schematic diagram of the polymer film after curing in the plasma cavity imaging structure according to an example of the present disclosure.

FIG. 4 schematically illustrates the structural schematic diagram of the removal of the surface transmissive metal film layer by stripping according to an example of the present disclosure.

FIG. 5 schematically illustrates a structural schematic diagram of a pattern structure obtained after development by a negative development process according to an example of the present disclosure.

FIG. 6 schematically illustrates the physical picture of the surface transmissive metal film layer before and after being stripped by PDMS polymer film, and the physical picture of the surface of the plasma cavity imaging structure after being stripped according to Example 1 of the present disclosure.

FIG. 7 schematically illustrates the physical picture of the surface transmissive metal film layer before and after being stripped by the polyvinyl alcohol-based polymer film, and the physical picture of the surface of the plasma cavity imaging structure after being stripped in Example 3 according to the present disclosure.

FIG. 8 schematically illustrates an electron microscope diagram of the surface of the plasma cavity imaging structure after the surface transmissive metal film layer is stripped by the PDMS polymer film in Example 1 according to the present disclosure.

FIG. 9 schematically illustrates an electron microscope diagram of the resolution of 64 nm obtained by negative development after the surface transmissive metal film layer is stripped by PDMS polymer film in Example 1 according to the present disclosure.

FIG. 10 schematically illustrates an electron microscope diagram after removing the surface Ag film by nitric acid in Comparative Example 1 according to the present disclosure.

### DESCRIPTION OF REFERENCE NUMERALS

1, substrate; 2, reflective metal film layer; 3, photosensitive film layer; 4, transmissive metal film layer; 5, mask light-blocking layer; 6, mask pattern structure; 7, mask substrate; 8, illuminating incident light; 9, polymer film.

### DETAILED DESCRIPTION OF EMBODIMENTS

In order to make the objectives, technical solutions and advantages of the present disclosure more clear, the present disclosure will be further described in detail hereinafter in connection with specific examples and with reference to the accompanying drawings.

The terms used herein are for the purpose of describing specific examples only and are not intended to limit the present disclosure. The terms “comprise”, “include” and the like used herein indicate the presence of the features, steps, operations and/or components, but do not exclude the presence or addition of one or more other features, steps, operations or components.

It should be noted that if there is a directional indication in the example of the present disclosure, the directional indication is only used to explain the relative position relationship and movement situation between components in a certain posture, and if the certain posture changes, the directional indication will also change accordingly.

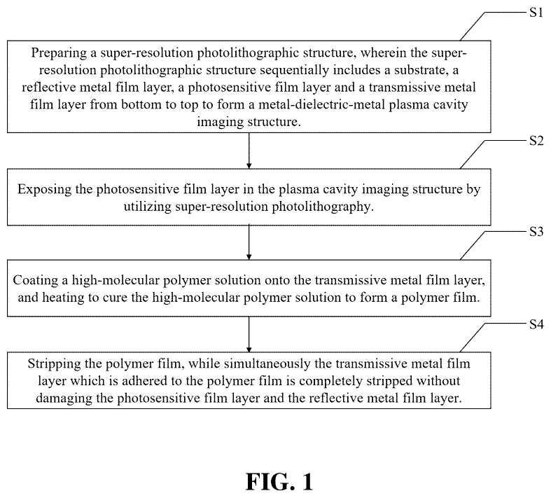

A method for removing a metal film layer from the surface of a substrate based on polymer material is provided in the present disclosure, as shown in FIG. 1, including: S1, preparing a super-resolution photolithographic structure, wherein the super-resolution photolithographic structure sequentially comprises a substrate 1, a reflective metal film layer 2, a photosensitive film layer 3 and a transmissive metal film layer 4 from bottom to top to form a metal-dielectric-metal plasma cavity imaging structure; S2, exposing the photosensitive film layer 3 in the plasma cavity imaging structure by utilizing super-resolution photolithography; S3, coating a high-molecular polymer solution onto the transmissive metal film layer 4, and heating to cure the high-molecular polymer solution to form a polymer film 9; and S4, stripping the polymer film 9, while simultaneously the transmissive metal film layer 4 which is adhered to the polymer film 9 is completely stripped without damaging the photosensitive film layer 3 and the reflective metal film layer 2.

In the method according to the present disclosure, firstly, an exposure process is carried out on the plasma cavity imaging structure by using super-resolution photolithography technology, and the exposed area of the photosensitive film layer 3 becomes a hydrophilic polymer, making water or a common alkaline solution (developer) cannot be used. Based on this, the high-molecular polymer solution is coated on the transmissive metal film layer 4 and cured to form a polymer film 9, wherein the polymer film 9 is closely bonded to the transmissive metal film layer 4. By utilizing the interfacial adhesion between the polymer film 9 and the transmissive metal film layer 4, the transmissive metal film layer 4 can be vertically stripped from the substrate 1, and the surface and structure of the lower photosensitive film layer 3 and the reflective metal film layer 2 will not be damaged or destroyed, which is beneficial to obtain high-quality super-resolution photolithography patterns.

On the basis of the above examples, S1 includes: preparing a reflective metal film layer 2 on a substrate 1 by a magnetron sputtering deposition, a thermal evaporation deposition or a chemical vapor deposition, wherein the substrate 1 includes one of a silicon substrate, a quartz substrate, a sapphire substrate, a magnesium fluoride substrate and a flexible substrate. The substrate 1 includes a planar substrate or a curved substrate. The material of the reflective metal film layer 2 includes one of Ag, Al and Au, with a thickness of 10-200 nm.

Firstly, a substrate 1 is selected, including but not limited to a planar substrate, and a curved substrate is also applicable. Optionally, the pretreatment steps, such as substrate cleaning, are included. An underlying reflective metal film layer 2 is prepared on the surface of a substrate 1. The reflective metal film layer 2 can be Ag, Al, Au, or other materials that can excite surface plasmons.

On the basis of the above example, S1 includes: preparing a transmissive metal film layer 4 on the photosensitive film layer 3 by a magnetron sputtering deposition, an atomic layer deposition, a chemical vapor deposition or a vacuum evaporation deposition, wherein the photosensitive film layer 3 includes one of AR series photoresist and AZ series photoresist, with a thickness of 10-200 nm. The material of the transmissive metal film layer 4 includes one of Ag, Al and Au, with a thickness of 10-30 nm.

A photosensitive film layer 3 is prepared on the underlying reflective metal film layer 2, and then a surface transmissive metal film layer 4 is prepared on the photosensitive film layer 3, so as to form a metal-photosensitive layer-metal plasma cavity imaging structure. The photosensitive film layer 3 can be made of other series of photosensitive materials such as AR series, AZ series or 365 nm wavelength photosensitive materials, and the surface transmissive metal film layer 4 can be made of Ag, Al, Au or other materials with a negative dielectric constant.

On the basis of the above example, S2 includes: exposing the photosensitive film layer in the plasma cavity imaging structure through a mask by using an ultraviolet illumination light source, wherein the mask pattern structure in the mask includes one of a one-dimensional pattern structure and a two-dimensional pattern structure.

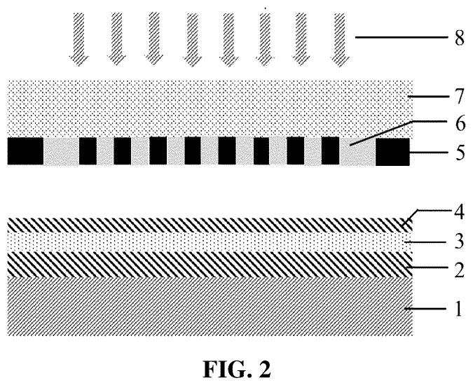

As shown in FIG. 2, the illuminating incident light 8 irradiates a mask, wherein the mask includes a mask substrate 7, a mask light-blocking layer 5 and a mask pattern structure 6, and the critical dimension of the mask pattern structure 6 is 20-64 nm. The ultraviolet illumination sources of 365 nm, ultraviolet illumination sources of 193 nm, and ultraviolet illumination sources of other bands can be adopted in the super-resolution photolithography technology.

On the basis of the above example, the high-molecular polymer solution includes: silicone rubber solution, or a combination solution of polyvinyl alcohol and polyvinylpyrrolidone, or a combination solution of polyvinyl alcohol and melamine. The polyvinyl alcohol has a polymerization degree of 500-2000 and an alcoholysis degree of 87%-89%. The high-molecular polymer solution is determined according to the bonding force between the photosensitive film layer 3 and the transmissive metal film layer 4.

After exposure, the surface metal of the plasma cavity imaging structure is stripped, wherein the stripping solution is a high-molecular polymer solution, and the stripping process includes coating-curing-tearing. The high-molecular polymer solution can be silicone rubber solution, such as polydimethylsiloxane (PDMS); it can further be a combination solution of polyvinyl alcohol (PVA) and melamine (M); it can further be a combination solution of polyvinyl alcohol and polyvinyl pyrrolidone (PVP). The adopted high-molecular polymer solution requires no reaction with metals and no production of other impurities. In addition, after the high-molecular polymer solution is cured into a film, it must have good adhesion with the surface transmissive metal film layer 4, wherein the adhesion must be stronger than that between the surface transmissive metal film layer 4 and the underlying photosensitive film layer 3, yet not excessive to prevent fall off or damage of the photosensitive film layer 3 from substrate 1. The adhesion between the polymer film 9 and the transmissive metal film layer 4 is determined by both the surface bonding force of the polymer film 9 and the transmissive metal film layer 4 and the cohesion of the polymer film 9 itself. Specifically, the microstructure of the surface of the transmissive metal film layer 4, the glass transition temperature of the high-molecular polymer, the polymerization degree, the degree of crosslinking, the degree of curing, viscosity, hydrophilicity and hydrophobicity all affect the final adhesion strength. By adjusting the above characteristics of the high-molecular polymer and controlling the interfacial adhesion between the polymer film 9 and the surface transmissive metal film layer 4, the surface transmissive metal film layer 4 can be vertically stripped from the substrate 1.

On the basis of the above example, the silicone rubber solution includes polydimethylsiloxane. S3 includes: S311, mixing polydimethylsiloxane and a curing agent uniformly to obtain a crosslinked mixed solution; S312, vacuumizing to remove bubbles in the mixed solution; S313, pouring the mixed solution obtained in S312 onto the transmissive metal film layer 4, and spin-coating at the rotating speed of 300-500 rpm for 30-60 seconds; and S314, heating at 75-85° C. for 15-25 minutes to cure the mixed solution, so as to form a polymer film 9.

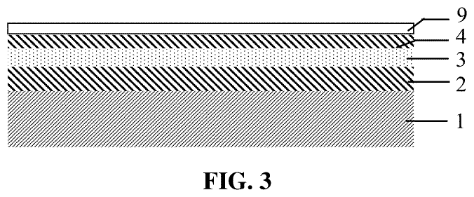

When PDMS is adopted as the stripping substrate of the surface transmissive metal film layer 4, polydimethylsiloxane and curing agent are thoroughly mixed according to the mass ratio of 3-4:1, so as to obtain a cross-linked mixed solution, wherein the viscosity of the obtained mixed solution is about 3500 mPa·s. Then the mixed solution is placed into a vacuum drying oven, and degassed for 20-30 minutes under a pressure condition of −5×10⁴ Pa to −9×10⁴ Pa to remove bubbles from the mixed solution. The prepared PDMS prepolymer is poured onto the plasma cavity imaging structure and spin-coated at 300-500 rpm for 30-60 seconds. Subsequently, it is placed on a hot plate and heated at 75-85° C. for 15-25 minutes to cure the PDMS, as shown in FIG. 3, so as to obtain the polymer film 9. The cured PDMS prepolymer is tightly bonded to the surface transmissive metal film layer 4. After the PDMS polymer film is cooled, the surface transmissive metal film layer 4 can be vertically stripped from the imaging substrate by relying on the interfacial adhesion between the PDMS film and the surface transmissive metal film layer 4.

On the basis of the above example, the high-molecular polymer solution is a combination solution of polyvinyl alcohol and melamine or a combination solution of polyvinyl alcohol and polyvinylpyrrolidone. S3 includes: S321, mixing polyvinyl alcohol, polyvinylpyrrolidone or melamine, and deionized water uniformly to obtain a mixed solution; S322, stirring the mixed solution fully in a water bath or an oil bath at 70-80° C. for 3-5 h, and standing; S323, pouring the mixed solution obtained in S322 onto the transmissive metal film layer 4, and spin-coating at the rotating speed of 300-500 rpm for 30-60 seconds; and S324, heating at 60-80° C. for 2-10 minutes to cure the mixed solution, so as to form a polymer film 9.

When the bonding force between the photosensitive film layer 3 and the surface transmissive metal film layer 4 is relatively large, the PDMS polymer film is no longer applicable. In this situation, the composite film of polyvinyl alcohol (PVA) and polyvinylpyrrolidone (PVP) can be adopted. The adhesion between the PVA polymer itself and the surface transmissive metal film layer 4 is slightly weak, which is not enough to completely strip the surface transmissive metal film layer 4 from the imaging substrate, and the strength (tensile strength and breaking strength) of the PVA film is not high enough, so that it is easy to break directly in the stripping process. Therefore, the adhesion between PVA film and surface transmissive metal film layer 4 is mainly controlled by PVA material selection, viscosity control, PVP composite modification and curing condition control. In the experiment, PVA with polymerization degree of 500-2000 and alcoholysis degree of 87%-89% was selected. This series of PVA has good water solubility and high strength. Moreover, in order to further improve the adhesion between PVA film and surface transmissive metal film layer 4, a certain amount of PVP is added to PVA polymer. On the one hand, PVP has good hydrophilicity and strong adhesion to the substrate after curing; on the other hand, the oxygen atoms in PVP molecular units and hydroxyl groups in PVA are easy to form strong hydrogen-bond interaction, which improves the cohesion of polymer films. For these two reasons, PVA/PVP composite films have good adhesion with metal substrates. PVA and PVP powder are mixed with deionized water according to the ratio of 15:1:44-5:1:14, and the mixed solution is thoroughly stirred in a water bath or oil bath at 70-80° C. for 3-5 h, and the viscosity is 20-30 mPa·s. After standing for 4-12 h, the PVA/PVP blending solution is poured onto the plasma cavity imaging structure and spin-coated for 30-60 seconds at the speed of 300-500 rpm, and then it is cured on a hot plate at 75° C. for 2-5 minutes, as shown in FIG. 3, so as to obtain the polymer film 9. The cured PVA/PVP composite film has good adhesion with the surface transmissive metal film layer 4, so that the surface transmissive metal film layer 4 can be vertically stripped from the imaging substrate.

When the bonding force between the photosensitive film layer 3 and the surface transmissive metal film layer 4 is excessively high, it may be difficult for the PVA/PVP composite film to completely strip the surface transmissive metal film layer 4 from the imaging substrate. In such cases, a certain amount of melamine (M) can be added to the PVA polymer to modify PVA film. As a small molecule, M can penetrate between the PVA molecular chains, and the amino groups on its side chains can form strong hydrogen bonds with the hydroxyl groups in the PVA molecules. This compensates for the insufficient intrinsic strength of PVA while enhancing both the cohesive force of the polymer film and the ultimate adhesion strength to the substrate. The adhesion between PVA/M composite film and the surface transmissive metal film layer 4 is stronger than that of PVA/PVP composite film. PVA, M powder and deionized water are mixed according to the ratio of 25:1:74-5:1:14, and the mixed solution is thoroughly stirred in a water bath or oil bath at 70-80° C. for 3-5 h, and then stands for 4-12 h, the viscosity is 25-35 mPa·s. The prepared PVA/M blending solution is poured on the plasma cavity imaging structure and spin-coated for 30-60 seconds at the rotating speed of 300-500 rpm, and it is cured on a hot plate at 65° C. for 5-10 minutes, or on a hot plate at 75° C. for 2-5 minutes, as shown in FIG. 3, so as to obtain the polymer film 9. Depending on the strong adhesion between PVA/M composite film and the surface transmissive metal film layer 4, the surface transmissive metal film layer 4 can be completely stripped vertically from the imaging substrate. When the polymer film 9 is stripped from the surface transmissive metal film layer 4, the imaging substrate can be placed on a vacuum chuck for operation. In addition, the selected high-molecular polymer solution must not only avoid reacting with the surface transmissive metal film layer 4, but also prevent the infiltration of the high-molecular polymer solution through the surface transmissive metal film layer 4 to react with the photosensitive film layer 3.

The stripping method of surface metal film layer disclosed by the present disclosure is simple, effective and nondestructive. The surface metal film layer can be completely stripped by adjusting the bonding force between the polymer film and the surface metal film layer, including but not limited to the removal of the surface metal film layer of the plasma cavity imaging structure, without damaging and destroying the photosensitive film layer and the underlying reflective metal film layer, thereby improving the photolithography quality of super-resolution patterns.

On the basis of the above example, S4 includes: adjusting the adhesion between the polymer film 9 and the transmissive metal film layer 4 by changing the viscosity and the degree of curing of the high-molecular polymer in the high-molecular polymer solution, so that the transmissive metal film layer 4 adheres to the polymer film 9 and is completely stripped, and the photosensitive film layer 3 and the reflective metal film layer 2 are not damaged.

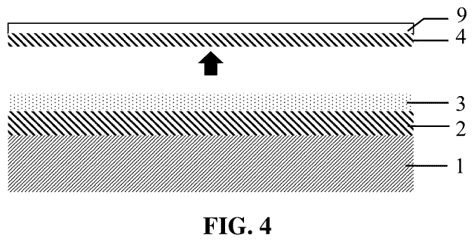

Since the bonding force between different series of photosensitive film layers 3 and surface transmissive metal film layer 4 is different, if the bonding force between photosensitive film layer 3 and surface transmissive metal film layer 4 is not excessively strong, the adhesion between polymer film 9 and surface transmissive metal layer 4 can be regulated by adjusting the degree of curing and viscosity of the high-molecular polymer, wherein viscosity is related to the polymerization degree of the high-molecular polymer and solution concentration, as shown in FIG. 4, so as to achieve stripping of the surface transmissive metal layer 4 without causing damage and destruction to the underlying photosensitive film layer 3 and reflective metal film layer 2.

According to the method for removing the metal film layer on the surface of the substrate based on the high molecular polymer as the adhesive layer disclosed by the present disclosure, the surface metal can be completely removed only by simply coating the high-molecular polymer solution (silicone, modified polyvinyl alcohol, etc.) onto the surface of the metal layer to be stripped, without damaging and destroying the SP resonant cavity imaging structure, thus being beneficial to obtain high-quality super-diffraction photolithography patterns. This method can be applied for metal film layer removal in both planar and curved SP resonance cavity imaging structures, and is suitable for the interface between photosensitive film layer and surface metal with different adhesion strength.

A photolithography method with removing a metal film layer from the surface of a substrate based on polymer material is further provided in the present disclosure, including: S1, preparing a super-resolution photolithographic structure, wherein the super-resolution photolithographic structure sequentially includes a substrate 1, a reflective metal film layer 2, a photosensitive film layer 3 and a transmissive metal film layer 4 from bottom to top to form a metal-dielectric-metal plasma cavity imaging structure; S2, exposing the photosensitive film layer 3 in the plasma cavity imaging structure by utilizing super-resolution photolithography; S3, coating a high-molecular polymer solution onto the transmissive metal film layer 4, and heating to cure the high-molecular polymer solution to form a polymer film 9; S4, stripping the polymer film 9, while simultaneously the transmissive metal film layer 4 which is adhered to the polymer film 9 is completely stripped without damaging the photosensitive film layer 3 and the reflective metal film layer 2; and S5, performing negative development on the photosensitive film layer 3 by using an organic solvent, so as to obtain a super-resolution photolithographic pattern structure.

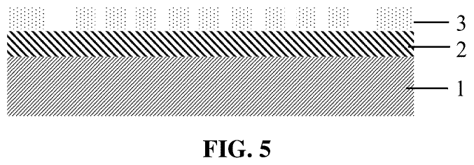

On the basis of the above technical solution, as shown in FIG. 5, a developing process can further be included. In order to obtain narrow trenches and small-sized through holes, negative development process can be adopted. After the surface transmissive metal film layer 4 is removed by the polymer film 9, neither rinsing with water nor additional dry etching processes are required for residual metal removal. The structure can be directly immersed in developing solution for development or subjected to spray development.

On the basis of the above example, the organic solvent in S5 includes one or more of ketones, ethers and esters.

In the negative development process, the organic solvents can be chosen as the developer, which can be ketones, ethers, esters, etc., and the developer only develops photosensitive patterns.

According to the present disclosure, by combining SP resonant cavity imaging technology with negative development process, the metal film layer on the surface of the substrate is completely removed, so that the protection of imaging structure and the improvement of photolithography pattern resolution and photolithography quality are realized, thus solving the problems that SP resonant cavity imaging structure in SP super-resolution imaging photolithography technology will cause damage and destruction of photosensitive film layer and underlying reflective metal film layer and influence photolithography pattern resolution and photolithography quality due to incompatibility with negative development process during the wet process of removing surface metal.

In the following, the present disclosure will be further explained by specific embodiments. In the following examples, the above-mentioned method for removing the metal film layer from the surface of substrate based on polymer material and the photolithography method are described in detail. However, the following examples are only used to illustrate the present disclosure, and the scope of the present disclosure is not limited thereto.

As shown in FIG. 2 to FIG. 5, the method for removing the metal film layer from the surface of substrate based on polymer material and the photolithography method disclosed by the present disclosure include conducting the following steps in sequence:
Step 1: selecting a substrate 1, including but not limited to a plane substrate, a curved substrate can also be used. Optionally, the pretreatment steps, such as substrate cleaning, are included.
Step 2: preparing an underlying reflective metal film layer 2 on the surface of the substrate 1, wherein the thickness of the underlying reflective metal film layer 2 is 10-200 nm.
Step 3: preparing a photosensitive film layer 3 on the underlying reflective metal film layer 2, wherein the thickness of the photosensitive film layer 3 is 10-200 nm;
Step 4: preparing a surface transmissive metal film layer 4 on the photosensitive film layer 3 to form a metal-photosensitive film layer-metal plasma cavity imaging structure, wherein the thickness of the surface transmissive metal film layer 4 is 10-30 nm, which is equivalent to the above step S1.
Step 5: carrying out an exposure process on the plasma cavity imaging structure by adopting the super-resolution photolithography technology, wherein the critical dimension of the adopted mask pattern is 20-64 nm, which is equivalent to the above step S2.
Step 6: stripping that surface transmissive metal film layer 4 of the plasma cavity image structure exposed in step 5, wherein the adopted stripping solution is a high-molecular polymer solution, and the stripping process includes coating-curing-tearing, which is equivalent to the above steps S3 to S4.
Step 7, developing the pattern in the photosensitive film layer 3 by adopting a developer to obtain a super-resolution photolithographic pattern structure, wherein the pattern can be a one-dimensional pattern or a two-dimensional pattern, and the critical dimension of the pattern is 20-64 nm, which is equivalent to the above step S5.

According to the above steps 1 to 7, three specific examples and one comparative example are provided below.

### Example 1

In the present example, the implementation steps of the method for removing a metal film layer from the surface of a substrate based on polymer material and the photolithography method were as follows:

Step 11: as shown in FIG. 2, the material of the substrate 1 was quartz. The underlying reflective metal film layer 2 was an Ag film layer with a thickness of 40 nm, and the preparation method was thermal evaporation coating or magnetron sputtering coating. The photosensitive film layer 3 was an AR-P 3170 photoresist layer with a film thickness of 20 nm. The surface transmissive metal film layer 4 was made of Ag with a thickness of 16 nm, and the preparation method was thermal evaporation coating. The mask light-blocking layer 5 was made of metal Cr with a thickness of 40 nm, and the preparation method was magnetron sputtering coating with a coating temperature of 400° C. The mask pattern was a grating pattern structure with a half period of 64 nm, the mask substrate 7 was a quartz substrate, and the illuminating incident light 8 used an ultraviolet light of 365 nm.

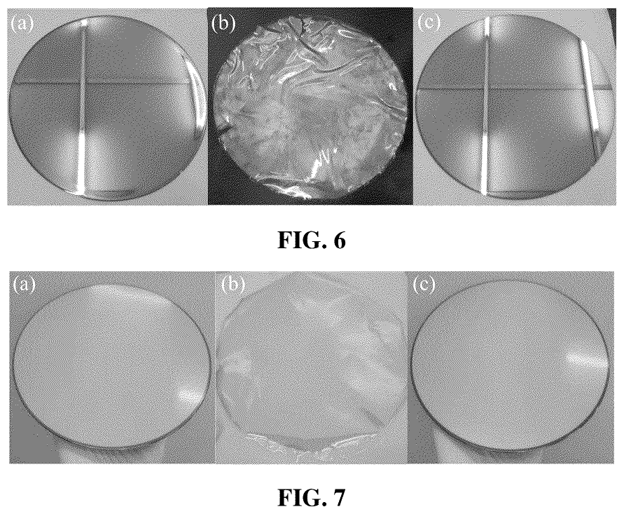

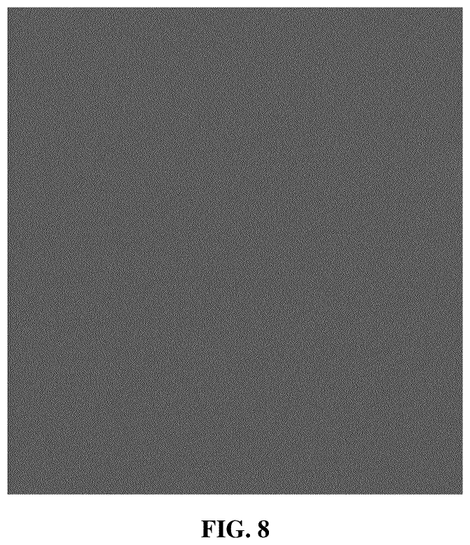

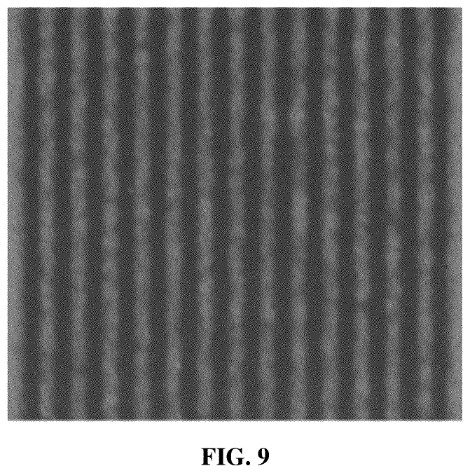

Step 12: as shown in FIG. 3, after the super-resolution photolithography exposure, the surface transmissive metal film layer 4 was stripped by using silicone rubber (polydimethylsiloxane, PDMS). The PDMS base material and curing agent were mixed in a weight ratio of 3-4:1 to obtain a mixed solution, wherein the viscosity of the mixed solution was about 3500 mPa·s. After thoroughly stirring, the mixed solution was degassed in a vacuum drying oven for 30 minutes to remove bubbles. The degassed mixed solution was poured onto the surface of the transmissive metal film layer 4 and was spin-coated for 60 s at the speed of 300-350 rpm, resulting in a film thickness of approximately 200 μm. The spin-coated prepolymer was placed on a hot plate for curing, with the curing temperature maintained at 75-80° C. for 15-20 minutes. After the sample was cooled to room temperature, the PDMS polymer film was lifted vertically from the substrate 1 with tweezers. At this time, the surface Ag film layer was adhered to the PDMS polymer film and stripped simultaneously. The structure after stripping is shown in FIG. 4. As shown in FIG. 6, it is a physical picture of removing the surface Ag film by using PDMS polymer as an adhesion layer. In FIG. 6, (a) is a physical picture of PDMS material coated and cured on an the surface of an 8-inch plasma cavity imaging structure; in FIG. 6, (b) is a physical picture of a PDMS polymer film carrying a surface transmissive metal film layer 4; and in FIG. 6, (c) is a physical picture of the surface of the plasma cavity imaging structure after the surface transmissive metal film layer 4 is stripped. By adjusting the ratio of PDMS base material to curing agent, the viscosity of prepolymer, selecting a certain spin coating rate to control the thickness of PDMS film, and choosing appropriate curing temperature and time, etc., the strength, hardness, and elastic modulus of PDMS polymer film can be regulated, and the final adhesion between PDMS polymer film and surface metal can be controlled. It can be observed that the surface Ag layer was completely stripped from the plasma cavity imaging structure. As shown in FIG. 8, it is the pattern of PDMS polymer film after removing the surface transmissive metal film layer 4. It can be seen that the photosensitive film layer 3 remains intact and undamaged. As shown in FIG. 5, after the surface Ag film was stripped by PDMS polymer film, no deionized water rinsing is required. The photosensitive film layer 3 is negatively developed with ethyl acetate as developer, with the developing time of 30 s and the developing temperature of 22° C. Due to the inability of the negative development process to use traditional water-based developer, traditional nitric acid and phosphoric acid contain a certain amount of moisture, and during wet etching to remove silver, they can cause damage and destruction to the photosensitive film layer 3 and the underlying reflective metal film layer 2. Therefore, after etching to remove silver, it is necessary to repeatedly rinse with deionized water to remove residues. The method disclosed by the present disclosure can overcome the incompatibility issues with subsequent processes encountered in conventional silver removal by nitric acid and phosphoric acid, and can avoid the damage to the photosensitive film layer 3 and the underlying reflective metal film layer 2, thus ensuring the quality of imaging patterns. The plasma cavity imaging structure in the present example achieves a pattern with resolution of 64 nm in super-resolution photolithography, and the contrast of the pattern reached above 0.7. Furthermore, through exposure and development processes, a resolution pattern of 64 nm is obtained, and the line edge roughness is smaller than that of conventional stripping surface Ag film by nitric acid and phosphoric acid, as shown in FIG. 9. This validates the advantages of using high-molecular polymer films for stripping (surface) metal as disclosed in the present disclosure.

### Example 2

In the present example, the implementation steps of the method for removing a metal film layer from the surface of a substrate based on polymer material and the photolithography method were as follows:

Step 21: as shown in FIG. 2, the material of the substrate 1 was sapphire. The underlying reflective metal film layer 2 was an Al film layer with a thickness of 80 nm, and the preparation method was magnetron sputtering coating. The photosensitive film layer 3 was a photoresist layer in phenolic resin system with a film thickness of 30 nm. The surface transmissive metal film layer 4 was made of Al with a thickness of 25 nm, and the preparation method was thermal evaporation coating. The mask light-blocking layer 5 was made of metal Mo with a thickness of 40 nm, and the preparation method was magnetron sputtering coating with a coating temperature of 380° C. The mask pattern was a grating pattern structure with a half period of 44 nm, the mask substrate 7 was a quartz substrate, and the illuminating incident light 8 was an ultraviolet light of 365 nm.

Step 22: as shown in FIG. 3, after the super-resolution photolithography exposure, the surface transmissive metal film layer 4 was stripped by using the composite film of polyvinyl alcohol and polyvinylpyrrolidone. Compounding polyvinyl alcohol with polyvinyl pyrrolidone, on the one hand, PVP has good hydrophilicity and strong adhesion to the substrate after curing; on the other hand, the oxygen atoms in PVP molecular units and hydroxyl groups in PVA are easy to form strong hydrogen-bond interaction, which improves the cohesion of polymer films. Finally, the good adhesion between PVA/PVP composite films and metal substrates is obtained. 25 g of PVA and 5 g of PVP powder were mixed with 70 mL of deionized water in proportion, and the mixed solution was thoroughly stirred in a water bath or oil bath at 70° C. for 5 h to obtain a blending solution, wherein the viscosity of the blending solution was 20-30 mPa·s. The PVA/PVP blending solution after standing for 12 h was poured onto the surface transmissive metal film layer 4 and spin-coated at 500 rpm for 60 seconds, and then it is baked on a hot plate at 75° C. for 3 minutes. After curing and it was cooled to room temperature, the polymer film of polyvinyl alcohol and polyvinylpyrrolidone was taken up from the plasma cavity imaging structure with tweezers, and the surface Al film was stripped together with the polymer film 9. After the surface Al film was stripped, no deionized water rinsing was required, and the photographic film layer 3 was developed directly with AR300-35 developer, with a development duration of 20 s and a development temperature of 0° C., so as to obtain a pattern with a resolution of 44 nm.

### Example 3

In the present example, the implementation steps of the method for removing a metal film layer from the surface based on polymer material of a substrate and the photolithography method were as follows:

Step 31: as shown in FIG. 2, the material of the substrate 1 was quartz. The underlying reflective metal film layer 2 was an Ag film layer with a thickness of 60 nm, and the preparation method was magnetron sputtering coating. The photosensitive film layer 3 was a photoresist in phenolic resin system with a film thickness of 30 nm. The surface transmissive metal film layer 4 was made of Ag with a thickness of 30 nm, and the preparation method was thermal evaporation coating. The mask light-blocking layer 5 was made of metal Mo with a thickness of 40 nm, and the preparation method was magnetron sputtering coating with a coating temperature of 380° C. The mask pattern was a grating pattern structure with a half period of 44 nm, the mask substrate 7 was a quartz substrate, and the illuminating incident light 8 was an ultraviolet light of 365 nm.

Step 32: as shown in FIG. 3, after the super-resolution photolithography exposure, the surface metal was stripped by using the composite film of polyvinyl alcohol and melamine. Polyvinyl alcohol and melamine were compounded. Melamine, as a small molecule, can penetrate between the polyvinyl alcohol molecular chains, and the amino group on melamine can combine with the hydroxyl group on the side chain of PVA molecule to form strong hydrogen bonds. This compensated for the insufficient intrinsic strength of PVA film while enhancing both the cohesive force of the polymer film and the ultimate adhesion strength with the substrate. The 0588 series polyvinyl alcohol was chosen, and 25 g polyvinyl alcohol and 1 g melamine solid powder were weighed respectively. After mixing, 74 mL of deionized water was added. The mixture was stirred in a magnetic stirrer at 300 rpm for 4 h, with the water bath temperature being maintained at 75° C. The well-stirred mixed solution was left standing at room temperature for 12 h. The mixed solution of polyvinyl alcohol and melamine was poured onto the surface of the transmissive metal film layer 4 and spin-coated at 500 rpm for 30 s, resulting in a film thickness of approximately 5 μm. Thermal curing was performed on a 60° C. hot plate for 10 min. After curing was completed, it was cooled to room temperature, the polyvinyl alcohol and melamine polymer film was vertically lifted from substrate 1 by using tweezers, with the surface Ag layer being simultaneously stripped along with the polymer film. As shown in FIG. 7, it is the physical picture of the surface Ag film stripped by using polyvinyl alcohol and melamine polymer film as an adhesive layer. In FIG. 7, (a) is the physical picture of polyvinyl alcohol and melamine combination solution coated and cured on the surface of an 8-inch plasma cavity imaging structure; in FIG. 7, (b) is the physical picture of the polyvinyl alcohol-based polymer film carrying a surface transmissive metal film layer 4; and in FIG. 7, (c) is the physical picture of the surface of the plasma cavity imaging structure after the surface transmissive metal film layer 4 is stripped. After the surface Ag film was stripped, no deionized water rinsing was required, and the photographic film layer 3 was developed directly with AR300-35 developer, with a development duration of 20 s and a development temperature of 0° C., so as to obtain a pattern with a resolution of 44 nm.

### Comparative Example 1

In the present comparative example, the implementation steps of the method for removing a metal film layer from the surface of a substrate based on polymer material and the photolithography method were as follows:

Step 41: as shown in FIG. 2, the material of the substrate 1 was quartz. The underlying reflective metal film layer 2 was an Ag film layer with a thickness of 40 nm. The photosensitive film layer 3 was a photoresist layer in phenolic resin system with a film thickness of 30 nm. The surface transmissive metal film layer 4 was made of Ag with a thickness of 16 nm, and the preparation method was thermal evaporation coating. The mask light-blocking layer 5 was made of metal Cr with a thickness of 40 nm, and the preparation method was magnetron sputtering coating with a coating temperature of 400° C. The mask pattern was a grating pattern structure with a half period of 32 nm, the mask substrate 7 was a quartz substrate, and the illuminating incident light 8 was an ultraviolet light of 365 nm.

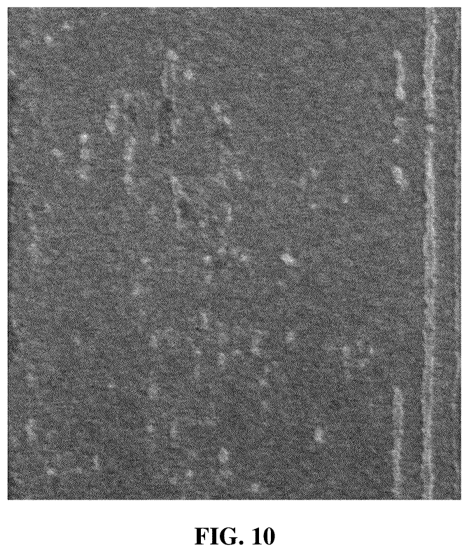

Step 42: After the super-resolution photolithography exposure, a nitric acid etching solution was adopted to conduct wet etching of the surface transmissive metal film layer 4, wherein the mass concentration of the nitric acid etching solution was 47%, the etching temperature was 22° C., and the etching duration was 15 s. After etching, the sample was rinsed thoroughly with deionized water. It can be found that the photosensitive film layer in phenolic resin system on the whole substrate has been completely corroded after etching, and only a small amount of photosensitive film layer remains, as shown in FIG. 10, so that subsequent process flows, such as development, cannot be carried out. Therefore, in order to prevent the photosensitive film layer and the underlying reflective metal film layer from being damaged and destroyed, additional protective layers (SiO₂, MgF₂, Si₃N₄, etc.) must be deposited on the surface of the photosensitive film layer and the underlying reflective metal film layer. The protective layers are generally prepared by magnetron sputtering deposition, atomic layer deposition, chemical vapor deposition, etc., which increases the process flow and cost.

In the present disclosure, the polymer film was selected as the adhesive layer, and the adhesion between the polymer film and the surface transmissive metal film layer was accurately regulated through the selection of high-molecular polymer, component control and optimization of process conditions, so that the surface transmissive metal film layer was successfully stripped completely without damage to the photosensitive film layer and the underlying reflective metal film layer. The present method overcomes the damage and destruction problems of the photosensitive film layer and the underlying metal caused by the conventional chemical liquid wet etching method. Compared with the conventional wet etching and dry etching (ion beam etching, reactive ion beam etching and inductively coupled plasma etching), the present method is simpler, lower in cost, and has no corrosion residue and surface metal residue. It also exhibits excellent compatibility with negative development processes, thus improving the photolithography quality of high-resolution patterns and providing a critical foundation for subsequent pattern transmission. By simply spin-coating the solution, curing it into a film, and performing a stripping process, the present method enables the super-resolution photolithography of 64 nm and below.

The specific examples described above further explain the objectives, technical solutions, and beneficial effects of the present disclosure. It should be understood that the above are only specific examples of the present disclosure and are not used to limit the present disclosure. Any modification, equivalent substitution, improvement, etc. made within the spirit and principle of the present disclosure should fall within the protection scope of the present disclosure.

1. A method for removing a metal film layer from a surface of a substrate based on polymer material, comprising:
S1, preparing a super-resolution photolithographic structure, wherein the super-resolution photolithographic structure sequentially comprises a substrate, a reflective metal film layer, a photosensitive film layer and a transmissive metal film layer from bottom to top to form a metal-dielectric-metal plasma cavity imaging structure;
S2, exposing the photosensitive film layer in the plasma cavity imaging structure by utilizing a super-resolution photolithography;
S3, coating a high-molecular polymer solution onto the transmissive metal film layer, and heating to cure the high-molecular polymer solution to form a polymer film; and
S4, stripping the polymer film, while simultaneously the transmissive metal film layer which is adhered to the polymer film is completely stripped without damaging the photosensitive film layer and the reflective metal film layer, wherein
the high-molecular polymer solution comprises:
a combination solution of a polyvinyl alcohol and a polyvinylpyrrolidone; or
a combination solution of the polyvinyl alcohol and a melamine, wherein
the polyvinyl alcohol has a polymerization degree of 500-2000 and an alcoholysis degree of 87%-89%; and
the high-molecular polymer solution is determined according to a bonding force between the photosensitive film layer and the transmissive metal film layer.

2. The method for removing the metal film layer from the surface of the substrate based on polymer material according to claim 1, wherein the S1 comprises:
preparing a reflective metal film layer on the substrate by a magnetron sputtering deposition, a thermal evaporation deposition or a chemical vapor deposition, wherein
the substrate comprises one of a silicon substrate, a quartz substrate, a sapphire substrate, a magnesium fluoride substrate and a flexible substrate; the substrate comprises a planar substrate or a curved substrate; and a material of the reflective metal film layer comprises one of Ag, Al and Au, with a thickness of 10-200 nm.

3. The method for removing the metal film layer from the surface of the substrate based on polymer material according to claim 1, wherein the S1 comprises:
preparing a transmissive metal film layer on the photosensitive film layer by a magnetron sputtering deposition, an atomic layer deposition, a chemical vapor deposition or a vacuum evaporation deposition, wherein
the photosensitive film layer comprises one of an AR series photoresist and an AZ series photoresist, with a thickness of 10-200 nm; and a material of the transmissive metal film layer comprises one of Ag, Al and Au, with a thickness of 10-30 nm.

4. The method for removing the metal film layer from the surface of the substrate based on polymer material according to claim 1, wherein the S2 comprises:
exposing the photosensitive film layer in the plasma cavity imaging structure through a mask by using an ultraviolet illumination light source, wherein a mask pattern structure in the mask comprises one of a one-dimensional pattern structure and a two-dimensional pattern structure.

5. (canceled)

6. (canceled)

7. The method for removing the metal film layer from the surface of the substrate based on polymer material according to claim 1, wherein the high-molecular polymer solution is the combination solution of the polyvinyl alcohol and the melamine or the combination solution of the polyvinyl alcohol and the polyvinylpyrrolidone; and the S3 comprises:
S321, mixing the polyvinyl alcohol, the polyvinylpyrrolidone, and a deionized water uniformly to obtain a mixed solution; or mixing the polyvinyl alcohol, the melamine, and the deionized water uniformly to obtain a mixed solution;
S322, stirring the mixed solution fully in a water bath or an oil bath at 70-80° C. for 3-5 h, and standing;
S323, pouring the mixed solution obtained in S322 onto the transmissive metal film layer and spin-coating at a rotating speed of 300-500 rpm for 30-60 seconds; and
S324, heating at 60-80° C. for 2-10 minutes to cure the mixed solution, so as to form a polymer film.

8. The method for removing the metal film layer from the surface of the substrate based on polymer material according to claim 1, wherein the S4 comprises:
adjusting an adhesion force between the polymer film and the transmissive metal film layer by changing a viscosity and a degree of curing of a high-molecular polymer in the high-molecular polymer solution, so that the transmissive metal film layer adheres to the polymer film and is completely stripped without damaging the photosensitive film layer and the reflective metal film layer.

9. A photolithography method with removing a metal film layer from a surface of a substrate based on polymer material, comprising:
S1, preparing a super-resolution photolithographic structure, wherein the super-resolution photolithographic structure sequentially comprises a substrate, a reflective metal film layer, a photosensitive film layer and a transmissive metal film layer from bottom to top to form a metal-dielectric-metal plasma cavity imaging structure;
S2, exposing the photosensitive film layer in the plasma cavity imaging structure by utilizing a super-resolution photolithography;
S3, coating a high-molecular polymer solution onto the transmissive metal film layer, and heating to cure the high-molecular polymer solution to form a polymer film;
S4, stripping the polymer film, while simultaneously the transmissive metal film layer which is adhered to the polymer film is completely stripped without damaging the photosensitive film layer and the reflective metal film layer; and
S5, performing a negative development on pattern in the photosensitive film layer by using an organic solvent, so as to obtain a super-resolution photolithographic pattern structure, wherein
the high-molecular polymer solution comprises:
a combination solution of a polyvinyl alcohol and a polyvinylpyrrolidone; or
a combination solution of the polyvinyl alcohol and a melamine, wherein
the polyvinyl alcohol has a polymerization degree of 500-2000 and an alcoholysis degree of 87%-89%; and
the high-molecular polymer solution is determined according to a bonding force between the photosensitive film layer and the transmissive metal film layer.

10. The photolithography method with removing the metal film layer from the surface of the substrate based on polymer material according to claim 9, wherein the organic solvent in the S5 comprises one or more of ketones, ethers and esters.
